(19) United States
(12) Patent Application Publication
(10) Pub. No.: US 2020/0161483 A1
(43) Pub. Date: May 21, 2020

(54) HOLE BLOCKING LAYERS FOR ELECTRONIC DEVICES AND METHOD OF PRODUCING AN ELECTRONIC DEVICE HAVING A HOLE-BLOCKING LAYER

(71) Applicant: KING ABDULLAH UNIVERSITY OF SCIENCE AND TECHNOLOGY, Thuwal (SA)

(72) Inventors: Xinbo YANG, Thuwal (SA); Stefaan DE WOLF, Thuwal (SA); Erkan AYDIN, Thuwal (SA)

(21) Appl. No.: 16/611,599

(22) PCT Filed: May 3, 2018
(86) PCT No.: PCT/IB2018/053087

§ 371 Date: Nov. 7, 2019

Related U.S. Application Data
(60) Provisional application No. 62/524,029, filed on Jun. 23, 2017.

(51) Int. Cl. H01L 31/0224; H01L 31/036; H01L 31/028; H01L 31/18

(52) U.S. Cl. CPC H01L 31/022425; H01L 31/1804; H01L 31/028; H01L 31/036

(57) ABSTRACT

A photovoltaic device includes an energy absorbing semiconductor substrate, a titanium nitride and/or tantalum nitride hole-blocking layer electrically coupled to the energy absorbing semiconductor substrate, and first and second electrodes electrically coupled to the energy absorbing semiconductor substrate.

### BACKGROUND

### Technical Field

Embodiments of the subject matter disclosed herein generally relate to hole-blocking layers for electronic devices and methods of producing such an electronic device.

### Discussion of the Background

Current extraction from electronic devices, such as photovoltaic devices, involves extracting electrons at one electrode (i.e., the cathode) and extracting holes at another electrode (i.e., the anode). Because current extraction is influenced by carrier recombination at the contact regions, hole- or electron-blocking layers are typically used in these types of electronic devices to improve current extraction. For example, a hole-blocking layer can reduce the hole concentration at the contact regions, which due to the asymmetric hole and electron concentration at the contact regions, reduces the carrier recombination. Those skilled in the art will recognize a hole is the absence of an electron in a particular location in an atom and holes are formed when an electron moves from the valence band into the conduction band.

Carrier blocking layers (i.e., layers blocking either electrons or holes) are formed in conventional silicon solar cells using high temperature diffusion to form a p-n junction. For example, a carrier blocking layer can be formed by phosphorous/boron diffusion at a temperature higher than 750° C. The high carrier recombination velocity at the surface of the doped regions requires application of dielectric passivation layers, which in turn requires a contact opening step for extraction of the photogenerated carriers. High carrier recombination at the metal-silicon contact regions also limits performance.

Titanium dioxide, lithium fluoride, magnesium fluoride, and magnesium oxide are currently being investigated as materials for a hole-blocking layer for silicon devices. The heterojunctions formed by these layers on silicon exhibit low contact resistivity, which improves device performance, particularly on an n-type silicon substrate on which is difficult to form ohmic-contact using conventional metals, such as aluminum and silver. Implementing these types of carrier blocking layers in silicon solar cells also eliminates the high temperature diffusion and contact opening steps required when a carrier blocking layer is formed using high temperature diffusion. However, most of these types of carrier blocking layers show high resistivity and poor stability, particularly for metal fluorides, which limits their industrial application.

Organic-inorganic hybrid perovskite light absorbers have recently emerged as a promising low-cost solar harvesting technology due to the improvement of conversion efficiency from 3.8% to >21%. High efficiency perovskite devices require high quality carrier blocking layers. Most current hole-blocking/electron transport layers for perovskite are based on transition metal oxides, such as titanium oxide, zinc oxide, and tin oxide. These metal oxides have high resistivity and low electron mobility, and thus improving the performance of perovskite devices with these blocking layers requires a high temperature annealing or doping process.

Organic semiconductors, such as the fullerene derivative [6,6]-phenyl-C₆₁-butyric acid methyl ester (PCBM), have also been investigated as a hole-blocking layer for perovskite solar cells. Devices with a PCBM blocking layer demonstrate poor stability, which is likely due to self-degradation in air through absorption of oxygen/water.

Accordingly, there is a need for a hole-blocking layer with low resistivity, high stability, and suitable band alignment with silicon and perovskite-based semiconductors for photovoltaic devices.

### SUMMARY

According to an embodiment, there is a photovoltaic device, which includes an energy absorbing semiconductor substrate, a titanium nitride and/or tantalum nitride hole-blocking layer electrically coupled to the energy absorbing semiconductor substrate, and first and second electrodes electrically coupled to the energy absorbing semiconductor substrate.

According to another embodiment, there is a method for producing a photovoltaic device. The method involves forming an energy absorbing semiconductor substrate, forming a titanium nitride and/or tantalum nitride hole-blocking layer adjacent to the energy absorbing semiconductor substrate, and forming a first electrode adjacent to the titanium nitride or tantalum nitride hole-blocking layer.

According to yet another embodiment, there is a photovoltaic device, which includes a perovskite energy absorbing semiconductor substrate, a first transparent conductive oxide layer arranged on a first side of the perovskite energy absorbing semiconductor substrate, a silicon energy absorbing semiconductor substrate arranged adjacent to a second side of the perovskite energy absorbing semiconductor substrate, and a titanium nitride and/or tantalum nitride hole-blocking layer arranged adjacent to the perovskite energy absorbing semiconductor substrate.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a schematic diagram of a silicon-based photovoltaic device according to an embodiment;

FIG. 2A is a graph illustrating the dependence of the resistivity of titanium nitride on the film thickness deposited by atomic layer deposition (ALD) according to an embodiment;

FIG. 2B is a graph illustrating the optical transmittance of titanium nitride thin films with different thickness deposited by ALD according to an embodiment;

FIG. 3A is a schematic illustration of relative band positions and work functions of titanium nitride, tantalum nitride, silicon, and perovskite thin films.

FIG. 3B is a graph illustrating dark I-V curves of Al/n-Si and Al/p-Si Schottky diodes with and without titanium nitride or tantalum nitride according to an embodiment;

FIGS. 4A, 4B, and 5-8 are schematics diagram of a silicon-based photovoltaic device according to additional embodiments;

FIGS. 9 and 10 are schematic diagrams of a perovskite-based photovoltaic device according to embodiments;

FIGS. 11 and 12 are schematic diagrams of silicon-perovskite tandem electronic devices according to embodiments;

FIG. 13 is a flow chart of a method for producing an n-type silicon-based photovoltaic device according to an embodiment;

FIG. 14 is a flow chart of a method for producing a p-type silicon-based photovoltaic device according to an embodiment; and

FIG. 15 is a flow chart of a method for producing a perovskite-based photovoltaic device according to an embodiment.

### DETAILED DESCRIPTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of electron extracting electronic devices.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a photovoltaic device includes an energy absorbing semiconductor substrate, first and second electrodes electrically coupled to the energy absorbing semiconductor substrate, and a titanium nitride or tantalum nitride hole-blocking layer electrically coupled to the energy absorbing semiconductor substrate.

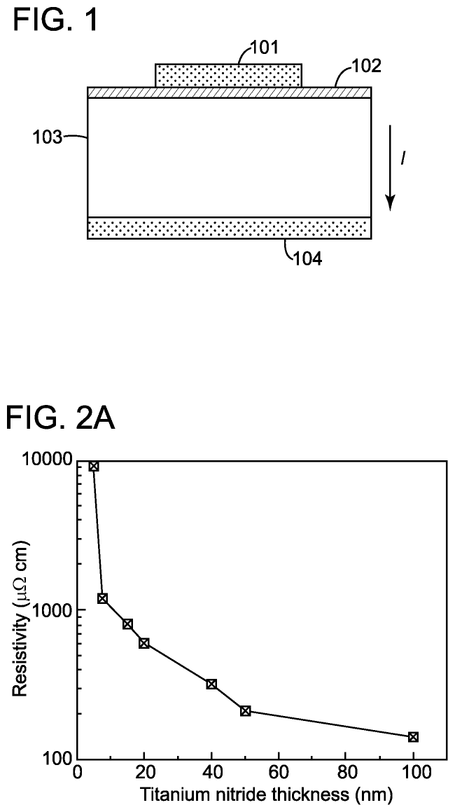

FIG. 1 is a schematic diagram of a photovoltaic device according to an embodiment. The front side of the device, which is the side on which incoming light impinges upon the device, includes a first electrode 101 arranged on top of a titanium nitride or tantalum nitride hole-blocking layer 102. The titanium nitride or tantalum nitride hole-blocking layer 102 is arranged directly adjacent to the semiconductor substrate 103, which includes a second electrode 104 on its back side. In this embodiment as well as the other disclosed embodiments, the titanium nitride or tantalum nitride hole-blocking layer can be a single titanium nitride or tantalum nitride hole-blocking layer or a stack of titanium nitride and/or tantalum nitride hole-blocking layers. The electrodes in this embodiment and the other disclosed embodiments can be made from materials in the group consisting of fluorine doped tin oxide (FTO), indium tin oxide (ITO), ZnO—Al₂O₃(AZO), tin oxide (SnO₂), zinc oxide (ZnO), indium oxide (In₂O₃), Zinc tin oxide (ZTO), indium zinc oxide (IZO), indium gallium zinc oxide (IGZO), cadmium oxide (CdO), silver nanowire network, graphene sheets, carbon nanotube (CNT), gold, silver, copper, rubidium, palladium, nickel, molybdenum, aluminum, alloys thereof, and multi-layer materials comprising the same.

In one embodiment, the semiconductor substrate 103 can be an n- or p-type silicon substrate. In other embodiments, which are detailed below, the semiconductor substrate is a perovskite-based semiconductor substrate.

Using a titanium nitride or tantalum nitride hole-blocking layer is particularly advantageous because this layer exhibits low resistivity, relatively high transparency in the visible spectral range, high chemical resistance, and suitable band alignment with silicon- and perovskite-based energy absorbing semiconductor substrates, such as those in photovoltaic devices.

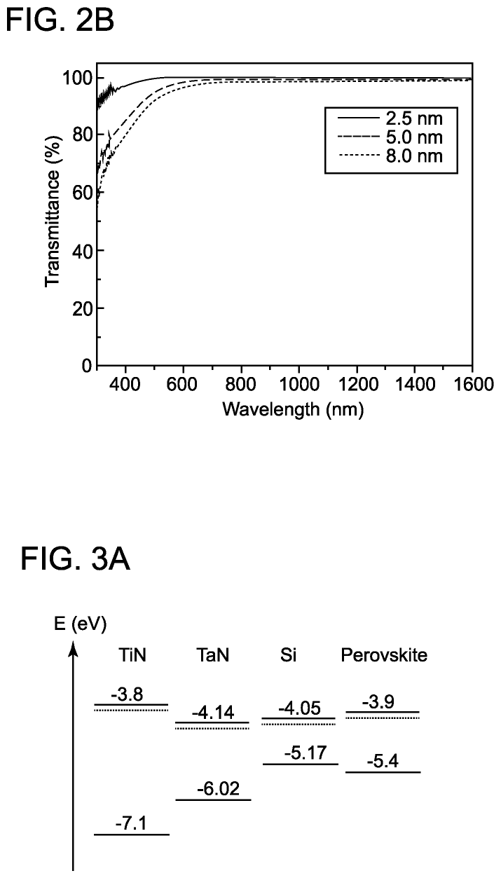

Specifically, as illustrated in FIG. 2A, which is a graph illustrating the dependence of the resistivity of titanium nitride on the film thickness deposited by ALD according to an embodiment, a titanium nitride layer exhibits low resistivity within the range of hole-blocking layer thickness used for photovoltaic devices. A tantalum nitride layer also exhibits low resistivity within the range of hole-blocking layer thickness used for photovoltaic devices. Further, titanium nitride and tantalum nitride layers are known to be chemically inert, which is advantageous because these layers will not chemically interact with adjacent layers, including an energy absorbing semiconductor substrate. The particular thickness of a titanium nitride or tantalum nitride hole-blocking layer can vary depending upon device structures. When the titanium nitride or tantalum nitride hole-blocking layer is arranged on the front-side of the device, the thickness can be, for example, between 1 and 10 nm. When the titanium nitride or tantalum nitride hole-blocking layer is arranged on the rear-side of the device, the thickness can be, for example, between 1 and 100 nm.

Additionally, as illustrated in FIG. 2B, which is a graph illustrating the transmittance of titanium nitride thin films with different thickness deposited by ALD according to an embodiment, titanium nitride is highly transparent in the visible light range for typical thicknesses of 2.5, 5.0, and 8.0 nm. A tantalum nitride layer also exhibits high transparency in the visible light range for these thicknesses.

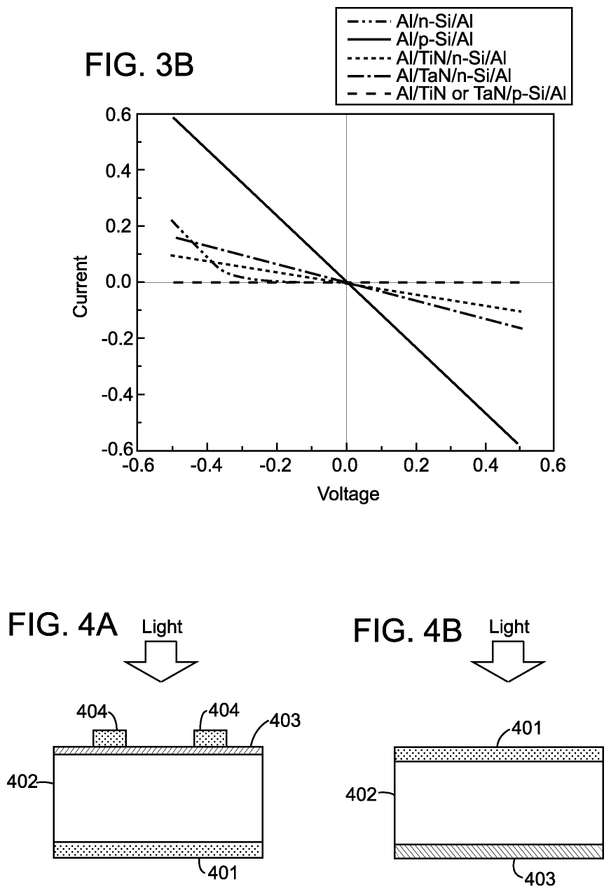

Moreover, as illustrated in FIG. 3A, titanium nitride (TiN) and tantalum nitride (TaN) show a suitable band alignment with silicon and perovskite. Thus, electrons generated in the silicon or perovskite substrate are able to pass through a titanium nitride or tantalum nitride layer, and collect at the electrode, due to a small conduction band offset.

Furthermore, as illustrated in FIG. 3B, a titanium nitride or tantalum nitride layer effectively blocks holes. Specifically, a diode with an n-type silicon substrate (Al/n-Si/Al in the figure) exhibits non-ohmic behavior, which is due to a large barrier height between the n-type silicon substrate and the aluminum. When a titanium nitride or tantalum nitride layer is interposed between the n-type silicon and the aluminum (Al/TiN/n-Si/Al and Al/TaN/n-Si/Al in the figure respectively) the dark current-voltage (I-V) curves exhibit ohmic behavior. In contrast, a diode with a p-type silicon substrate (Al/p-Si/Al in the figure) exhibits ohmic behavior and when a titanium nitride or tantalum nitride layer is interposed between the n-type silicon and the aluminum (Al/TiN/p-Si/Al and Al/TaN/p-Si/Al in the figure respectively) the current-voltage (I-V) curves exhibit non-ohmic behavior. Thus, titanium nitride and tantalum nitride layers effectively block holes for both n- and p-type silicon substrates and reduce the contact resistivity between the n-type silicon and aluminum.

The titanium nitride and tantalum nitride layers can take any number of forms, including TiN, Ti₂N, and other non-stoichiometric compositions for titanium nitride layers and TaN, Ta₃N₅, Ta₂N, Ta₄N₆, Ta₄N₅, and other non-stoichiometric compositions for tantalum nitride. The titanium nitride and tantalum nitride layers should primarily comprise a mix of any of the forms of titanium nitride and tantalum nitride, respectively. Other elements may be included, such as oxygen, but the layers should primarily contain titanium and nitrogen or tantalum and nitrogen. For example, a layer should contain at most 30% oxygen or other elements and at least 70% titanium and nitride or tantalum and nitride.

Various configurations of titanium nitride and tantalum nitride hole-blocking layers will now be described in connection with photovoltaic devices illustrated in FIGS. 4A-12.

The electronic device illustrated in FIG. 4A includes a first electrode 401 on the device's back side adjoining a p-type silicon substrate 402. The front side of the device includes a titanium nitride or tantalum nitride hole-blocking layer 403 directly adjacent to the p-type silicon substrate 402. Second electrodes 404 are directly adjacent to the titanium nitride or tantalum nitride hole-blocking layer 403.

The electronic device illustrated in FIG. 4B is similar to electronic device FIG. 4A, except that first electrode 401 is arranged on the front side of the device, the titanium nitride or tantalum nitride hole-blocking layer 403 is arranged on the back side of the electronic device, and the titanium nitride or tantalum nitride hole-blocking layer 403 also functions as an electrode, and thus the electronic device of FIG. 4B does not require second electrodes 404. Similar to the electronic device of FIG. 4A, the substrate 402 of the electronic device of FIG. 4B is a p-type silicon substrate.

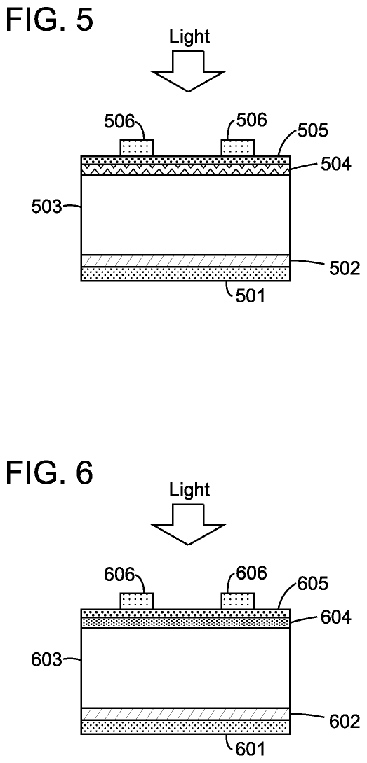

The electronic device illustrated in FIG. 5 includes a hole-blocking layer on the rear side of the electronic device and p-n homojunction on the front side of the device. Specifically, the electronic device includes a first electrode 501 directly adjacent to a titanium nitride or tantalum nitride hole-blocking layer 502. The titanium nitride or tantalum nitride hole-blocking layer 502 is directly adjacent to n-type silicon substrate 503. A p-n homojunction 504 is directly adjacent to n-type silicon substrate 503. A surface passivation layer 505 is interposed between, and directly adjacent to, the p-n homojunction 504 and electrodes 506.

The electronic device illustrated in FIG. 6 includes both a hole-blocking layer and an electron-blocking layer. Specifically, a first electrode 601 is formed on the back side of the electronic device and is directly adjacent to an electron-blocking layer 602. The electron-blocking layer in this embodiment as well as other embodiments can be selected from a group consisting of: 2,2′,7,7′-tetrakis(N,N-p-dimethoxyphenylamino)-9,9-spirobifluorene (spiro-OMeTAD), poly(3,4-ethylenedioxythiophene)-poly(styrenesulfonate)(PEDOT:PSS), N,N′-bis(3-methylphenyl)-N,N′-bis(phenyl)benzidine (TPD), poly(3-hexylthiophene) (P₃HT), copper thiocyanate (CuSCN), Poly[bis(4-phenyl)(2,5,6-trimentlyphenyl)amine (PTAA), nickel oxide (NiOₓ), vanadium oxide (VOₓ), copper (I) oxide (Cu₂O), molybdenum oxide (MoOₓ), copper iodide (CuI), copper(II) phthalocyanine (CuPc), copper oxide (CuOₓ), tungsten oxide (WOₓ), nickel oxide (NiO), vanadium pentoxide (V₂O₅), copper (I) oxide (Cu₂O), molybdenum oxide (MoO₃), copper iodide (CuI), copper (II) phthalocynaine (CuPc), copper oxide (CuOₓ), and tungsten oxide (WO₃).

The electron-blocking layer 602 is directly adjacent to an p-type silicon substrate 603. A titanium nitride or tantalum nitride hole-blocking layer 604 is directly adjacent to the p-type silicon substrate 603. A transparent conductive oxide layer 605 is interposed between, and directly adjacent to, the titanium nitride or tantalum nitride hole-blocking layer 604 and second electrodes 606.

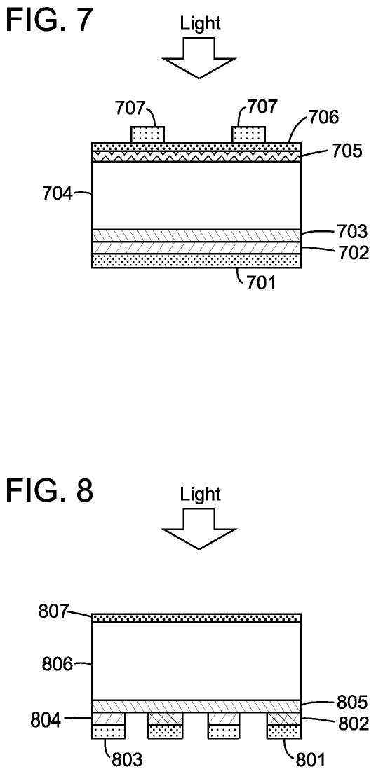

FIG. 7 illustrates an electronic device having double heterojunctions. Specifically, a first electrode 701 is directly adjacent to a titanium nitride or tantalum nitride hole-blocking layer 702. A first surface passivation interlayer 703 is interposed between, and directly adjacent to, titanium nitride or tantalum nitride hole-blocking layer 702 and a p- or n-type silicon substrate 704. A second surface passivation interlayer 705 is directly adjacent to the p- or n-type silicon substrate 704. An electron-blocking layer 706 is interposed between, and directly adjacent to, the second surface passivation layer 705 and second electrodes 707.

The electronic device illustrated in FIG. 8 is an interdigitated back-contact silicon device with both a hole-blocking and electron-blocking layer. Specifically, the interdigitated back-contact structure includes a first electrode 801 directly adjacent to a titanium nitride or tantalum nitride hole-blocking layer 802 and a second electrode 803 directly adjacent to an electron-blocking layer 804. As illustrated, the device back side includes two separate contacts comprising a first electrode 801 and the hole-blocking layer 802 and a second electrode 803 and the electron-blocking layer 804; however, for ease of illustration, only one of each type of contact is labeled in the figure. The interdigitated back-contact structure is directly adjacent to a first surface passivation interlay 805, which in turn is directly adjacent to an n- or p-type silicon substrate 806. A second surface passivation layer 807 is directly adjacent to the n- or p-type silicon substrate 806.

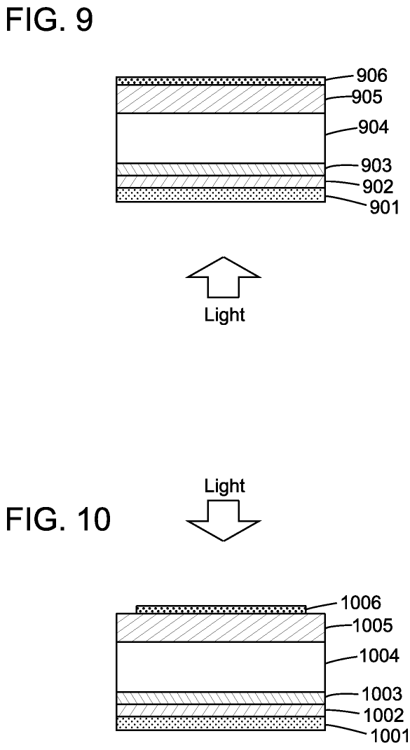

The electronic devices illustrated in FIGS. 4A-8 employ silicon semiconductor substrates. In contrast, the devices illustrated in FIGS. 9 and 10 employ perovskite-based semiconductor substrates. The perovskite layer can be selected from at least one of the compounds represented by the following formula:

ABX₃

wherein, A is an organic and/or inorganic cation (e.g., CH₃NH₃⁺, CH(NH₂)₂⁺, Cs⁺, Rb⁺) or independently H, a linear C1-10 alkyl or branched C1-10 alkyl; B is an inorganic cation (e.g., Pb, Sn, Bi, Cu, Fe, Co, Ni, Mn, or Cd; X is Cl, Br, or I.

The front side of the device includes a transparent substrate 901, which is directly adjacent to a transparent conductive oxide thin film 902. The transparent substrate 901 can be selected from the group consisting of glass and polymer foils. A titanium nitride or tantalum nitride hole-blocking layer 903 is between the transparent conductive oxide 902 and perovskite absorber 904. A perovskite absorber 904 is interposed between, and directly adjacent to, the titanium nitride or tantalum nitride hole-blocking layer 903 and electron-blocking layer 905. The back side of the device includes a back electrode 906 directly adjacent to the electron-blocking layer 905.

The electronic device illustrated in FIG. 10 is arranged so that the light enters the device from the opposite side compared to the electronic device illustrated in FIG. 9. The arrangement of FIG. 10 allows a novel device structure design because the perovskite solar cells can be grown on substrates such as flexible polymer foils, as well as stainless steel and other metal foils. The back side of the device includes a substrate 1001 directly adjacent to a first electrode 1002, which in turn is directly adjacent to a titanium nitride or tantalum nitride hole-blocking layer 1003. The substrate 1001 can be selected from the group consisting of polymer foils, stainless steel, and other metal foils. A perovskite absorber 1004 is interposed between, and is directly adjacent to, the titanium nitride or tantalum nitride hole-blocking layer 1003 and a hole-blocking layer 1005. A front transparent or patterned electrode 1006 is directly adjacent to the hole-blocking layer 1005.

Fabricating the electronic device in an inverted (p-i-n) configuration as illustrated in FIG. 10 allows the titanium nitride or tantalum nitride to function as both a hole-blocking layer and a moisture protection layer. This is advantageous because perovskite absorbers are easily degraded when exposed to the atmosphere due to humidity. Further, titanium nitride and tantalum nitride thin-films are chemically durable, and thus these layers can increase the stability of the perovskite-based devices.

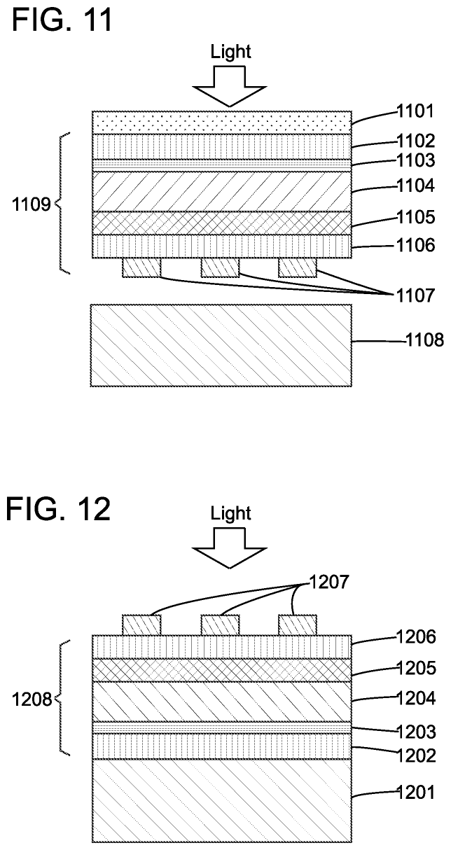

FIGS. 11 and 12 respectively illustrate four-terminal (4T) and two-terminal (2T) silicon-perovskite tandem electronic devices. The four-terminal electronic device illustrated in FIG. 11 includes a perovskite top cell 1109, comprising layers 1101-1107, optically coupled with a silicon bottom cell 1108. Specifically, the perovskite top cell 1109 is fabricated on a glass substrate 1101, which is directly adjacent to a first transparent conductive oxide layer 1102. A titanium nitride or tantalum nitride hole-blocking layer 1103 is interposed between, and directly adjacent to, the first transparent conductive oxide layer 1102 and a perovskite absorber layer 1104. The perovskite absorber layer 1104 is directly adjacent to an electron-blocking layer 1105, which in turn is directly adjacent to a second transparent conductive oxide layer 1106. Metal fingers 1107 are interposed between, and directly adjacent to, the second transparent conductive oxide layer 1106 and the silicon bottom cell 1108, which can include an n-type or p-type silicon wafer. The first and second conductive oxide layers 1102 and 1106 should have lateral conductivity to collect the charges. The production of the four-terminal device in FIG. 11 involves two metallization steps for both the silicon bottom cell 1102 and the perovskite top cell 1109, which in turn requires alignment of metal fingers 1107 when the silicon bottom cell 1102 and the perovskite top cell 1109 are joined together.

The four-terminal tandem configuration illustrated in FIG. 11 can use perovskite tops cells 1109 of different polarities, which allows independent fabrication of the perovskite top cell 1109 and silicon bottom cell 1108. Further, the four-terminal tandem electronic device illustrated in FIG. 11 does not require current matching between the perovskite top cell 1109 and the silicon bottom cell 1108.

In contrast to the requirement of two metallization steps for the top and bottom cells and metal finger alignment in the four-terminal electronic device illustrated in FIG. 11, the two-terminal device of FIG. 12 requires only one metallization step on the top of the final device and there is no need for metal finger alignment. The two-terminal electronic device illustrated in FIG. 12 includes a perovskite top cell 1208 that is fabricated directly on a silicon bottom cell 1201. Specifically, a transparent recombination layer 1202 is interposed between, and directly adjacent to, the silicon bottom cell and a titanium nitride or tantalum nitride hole-blocking layer 1203. The transparent recombination layer 1202 can be, for example, a transparent conductive oxide layer. In some embodiments, the transparent recombination layer 1202 can be eliminated, in which case the titanium nitride or tantalum nitride hole-blocking layer acts as the recombination layer in addition to acting as a hole-blocking layer. The titanium nitride or tantalum nitride hole-blocking layer 1203 acts as a tunneling junction and is directly adjacent to a perovskite absorber layer 1204, which in turn is directly adjacent an electron-blocking layer 1205. A transparent conductive oxide layer 1206 is interposed between, and directly adjacent to, the electron-blocking layer 1205 and metal fingers 1207. In this arrangement, the perovskite top cell 1208 is electrically coupled with the silicon bottom cell 1108.

The two-terminal tandem configuration allows the use of only one or two transparent conductive oxide layers, which simplifies fabrication and reduces fabrication costs. Specifically, each layer introduces some amount of optical losses, and therefore, eliminating one of the conductive oxide layers reduces parasitic absorption losses due to the conductive oxide layer. It will be recognized that parasitic absorption losses refer to an optical absorption process that does not generate an electron/hole pair; instead it competes with band-to-band absorption to decrease the photocurrent. Further, titanium nitride and tantalum nitride have very low parasitic absorption in the absorption range of perovskite and silicon solar cells, which helps increase the total current density of the tandem device. Integration of the perovskite top cell 1208 and the silicon bottom cell 1201 does not require contact alignment. Additionally, the use of a two-terminal tandem solar cell only requires a single inverter, which decreases the installation costs of such devices.

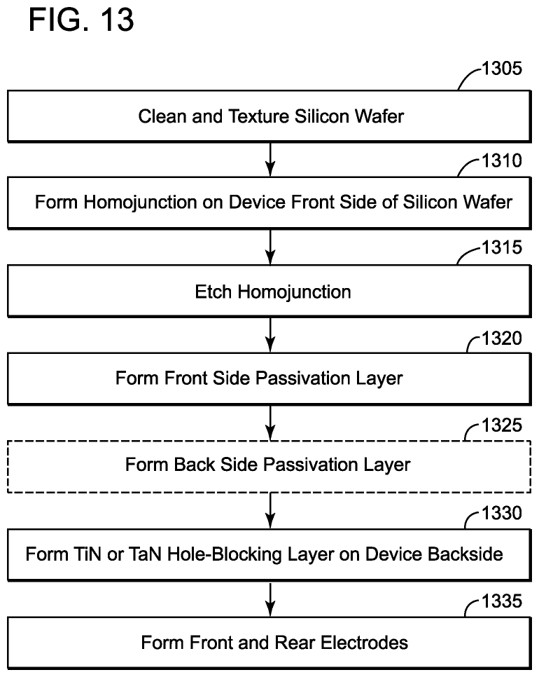

FIG. 13 is a flow chart of a method for producing an n-type silicon-based electron extracting electronic device, such as the electronic device illustrated in FIG. 5. An n-type silicon wafer 503 is initially cleaned and textured (step 1305). The n-type silicon wafer can have a resistivity of, for example, 1.0-5.0 Ωcm. A boron-doped p⁺ emitter homojunction 504 is formed on the device front side of the silicon wafer 503 (step 1310). The forming of the homojunction 504 can be performed using, for example, diffusion in a tube furnace. The homojunction 504 is etched (step 1315), for example the boron silicate glass can be etched in a diluted hydrofluoric acid (HF) solution.

The homojunction 504 is passivated by a front side passivation layer 505 formed on the homojunction 504 to reduce the carrier recombination at the front side of the device (step 1320). The passivation layer 505 can be, for example, an Al₂O₃/SiNₓ stack. An optional step that improves surface passivation involves depositing a surface passivation interlayer, for example hydrogenated amorphous silicon or silicon dioxide, on the device back side of the silicon wafer 503 (step 1325). A titanium nitride or tantalum nitride hole blocking layer 502 is then formed either directly on the device back side of the silicon wafer 503 (assuming there is no device back side passivation layer) or on the device back side passivation layer (step 1330). The titanium nitride or tantalum nitride hole blocking layer 502 can be formed using, for example, atomic layer deposition (ALD) or sputtering. The front and rear electrodes 501 and 506 are then formed by, for example, screen print with silver paste or electronic-plating (step 1335).

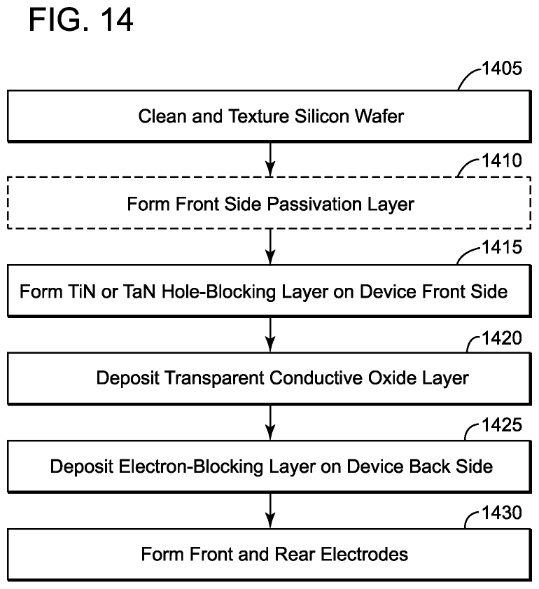

FIG. 14 is a flow chart of a method for producing a p-type silicon-based electron extracting electronic device, such as the electronic device illustrated in FIG. 6. A p-type silicon wafer 603 is initially cleaned and textured (step 1405). The p-type silicon wafer can have a resistivity of, for example, 1.0-5.0 Ωcm. An optional step that improves surface passivation involves depositing a surface passivation interlayer, for example hydrogenated amorphous silicon or silicon dioxide, on the device back side of the silicon wafer 603 (step 1410). A titanium nitride or tantalum nitride hole blocking layer 604 is then formed either directly on the device front side of the silicon wafer 603 (assuming there is no device back side passivation layer) or on the device front side passivation layer (step 1415).

A transparent conductive oxide layer 605, for example of indium doped tin oxide (ITO), is then deposited on the titanium nitride or tantalum nitride hole blocking layer 604 in order to reduce lateral transport resistance and maximize light coupling (step 1420). An electron-blocking layer 602 is formed on the device back side of the silicon wafer 603 (step 1425). The front and rear electrodes 601 and 606 are then formed by, for example, screen print with silver paste or electroplating (step 1430).

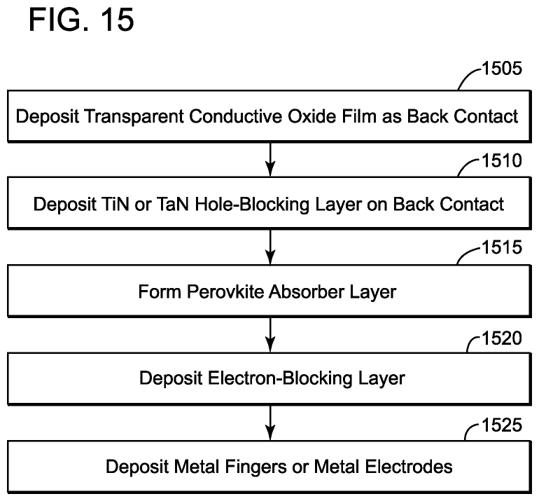

FIG. 15 illustrates a flow chart of a method for producing a perovskite-based electron extracting electronic device, such as the electronic device illustrated in FIG. 9. A transparent substrate 901 is formed, for example by sputtering, pulsed laser deposition or atomic layer deposition as a back contact (step 1505). A titanium nitride or tantalum nitride hole-blocking layer 902 is formed on the back contact by, for example, atomic layer deposition or sputter (step 1510). A perovskite absorber layer 903 is formed by, for example, spin-coating, blading, slot die coating, spray pyrolysis, ink-jet printing, or evaporation (step 1515). An electron-blocking layer 904 is then deposited on the perovskite layer 903 using, for example, sputtering, spin-coating, blading, spray deposition, ink-jet printing, or evaporation (step 1520). Metal fingers or metal electrodes 905 are formed on the electron-blocking layer 904 by, for example, thermal evaporation, electron-beam evaporation, or ink-jet printing (step 1525).

Although the embodiments discussed above involve photovoltaic devices, the disclosed titanium nitride and/or tantalum nitride hole-blocking layers can be used in a wide variety of electronic devices, including bipolar transistors, light emitting diodes, laser diodes, or any other type of electronic device where a hole-blocking layer is desirable.

The disclosed embodiments provide hole-blocking layers for electronic devices and methods for producing electronic devices having a hole-blocking layer. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A photovoltaic device, comprising:
an energy absorbing semiconductor substrate;
a titanium nitride and/or tantalum nitride hole-blocking layer electrically coupled to the energy absorbing semiconductor substrate; and
the first and second electrodes electrically coupled to the energy absorbing semiconductor substrate.

2. The photovoltaic device of claim 1, wherein the energy absorbing semiconductor substrate is silicon or perovskite.

3. The photovoltaic device of claim 1, wherein the energy absorbing semiconductor substrate and the titanium nitride and/or tantalum hole-blocking layer are transparent to visible light.

4. The photovoltaic device of claim 1, wherein the titanium nitride or tantalum nitride hole-blocking layer forms one of the first and second electrodes.

5. The photovoltaic device of claim 1, wherein the titanium nitride or tantalum nitride hole-blocking layer is directly adjacent to the energy absorbing semiconductor substrate.

6. The photovoltaic device of claim 1, wherein a surface passivation layer is interposed between the titanium nitride or tantalum nitride hole-blocking layer and the energy absorbing semiconductor substrate.

7. The photovoltaic device of claim 6, wherein the first electrode is directly adjacent to the surface passivation layer, the electronic device further comprising:
an electron-blocking layer interposed between the surface passivation layer and the second electrode.

8. The photovoltaic device of claim 1, further comprising:
an electron-blocking layer interposed between one of the first and second electrodes and the energy absorbing semiconductor substrate.

9. The photovoltaic device of claim 1, wherein the energy absorbing semiconductor substrate is perovskite, the electronic device further comprising:
a silicon energy absorbing semiconductor substrate electrically coupled to the perovskite energy absorbing semiconductor substrate.

10. A method for producing a photovoltaic device, the method comprising:
forming an energy absorbing semiconductor substrate;
forming a titanium nitride and/or tantalum nitride hole-blocking layer adjacent to the energy absorbing semiconductor substrate; and
forming a first electrode adjacent to the titanium nitride or tantalum nitride hole-blocking layer.

11. The method of claim 10, further comprising:
forming a passivation layer on the energy absorbing semiconductor substrate, wherein the titanium nitride or tantalum nitride hole-blocking layer adjacent to the energy absorbing semiconductor substrate is formed on the passivation layer.

12. The method of claim 10, further comprising:
forming an electron-blocking layer adjacent to the energy absorbing semiconductor substrate and on a side of the semiconductor substrate opposite to a side of the energy absorbing semiconductor substrate on which the titanium nitride or tantalum nitride hole-blocking layer adjacent to the energy absorbing semiconductor substrate is formed.

13. The method of claim 10, wherein the energy absorbing semiconductor substrate is a silicon substrate, the method further comprising:
forming a doped homojunction on the silicon substrate.

14. The method of claim 10, wherein the energy absorbing semiconductor substrate is a perovskite substrate, the method further comprising:
forming a transparent substrate, wherein the titanium nitride or tantalum nitride hole-blocking layer is formed on the transparent substrate.

15. The method of claim 14, wherein the perovskite substrate is formed by one of spin-coating, blading, slot die coating, spray pyrolysis, ink-jet printing, and evaporation.

16. A photovoltaic device, comprising:
a perovskite energy absorbing semiconductor substrate;
a first transparent conductive oxide layer arranged on a first side of the perovskite energy absorbing semiconductor substrate;
a silicon energy absorbing semiconductor substrate arranged adjacent to a second side of the perovskite energy absorbing semiconductor substrate; and
a titanium nitride and/or tantalum nitride hole-blocking layer arranged adjacent to the perovskite energy absorbing semiconductor substrate.

17. The photovoltaic device of claim 16, wherein the titanium nitride or tantalum nitride hole-blocking layer is interposed between the first transparent conductive oxide layer and the perovskite energy absorbing semiconductor substrate.

18. The photovoltaic device of claim 17, further comprising:
a second transparent conductive oxide layer interposed between the perovskite energy absorbing semiconductor substrate and the silicon energy absorbing substrate; and
an electron-blocking layer interposed between the second side of the perovskite energy absorbing semiconductor substrate and the second transparent conductive oxide layer.

19. The photovoltaic device of claim 16, further comprising:
a second transparent conductive oxide layer interposed between the perovskite energy absorbing semiconductor substrate and the silicon energy absorbing substrate, wherein the titanium nitride or tantalum nitride hole-blocking layer is interposed between the second transparent conductive oxide and the perovskite energy absorbing semiconductor substrate.

20. The photovoltaic device of claim 17, further comprising:
an electron-blocking layer interposed between the first side of the perovskite energy absorbing semiconductor substrate and the first transparent electrode.
